(19) United States
(12) Patent Application Publication
(10) Pub. No.: US 2021/0305769 A1
(43) Pub. Date: Sep. 30, 2021

(54) QUANTUM CASCADE LASER

(71) Applicant: SUMITOMO ELECTRIC INDUSTRIES, LTD., Osaka-shi (JP)

(72) Inventor: Jun-ichi HASHIMOTO, Osaka-shi (JP)

(73) Assignee: SUMITOMO ELECTRIC INDUSTRIES, LTD., Osaka-shi (JP)

(21) Appl. No.: 17/173,597

(22) Filed: Feb. 11, 2021

(30) Foreign Application Priority Data
Mar. 24, 2020 (JP) 2020-053053

(51) Int. Cl. H01S 5/026; H01S 5/34; H01S 5/22; H01S 5/042; H01S 5/20

(52) U.S. Cl. CPC H01S 5/026; H01S 5/3402; H01S 5/2018; H01S 5/04256; H01S 5/22

(57) ABSTRACT

A quantum cascade laser includes a first mesa waveguide provided on a substrate, the first mesa waveguide including a first core layer, a second mesa waveguide provided on the substrate, the second mesa waveguide including a second core layer, a first electrode electrically connected to the first mesa waveguide, and a second electrode electrically connected to the second mesa waveguide. The first mesa waveguide and the second mesa waveguide extend in a first direction. The first mesa waveguide and the second mesa waveguide are apart from each other by a first distance in a second direction, the second direction intersecting with the first direction. The first electrode and the second electrode are apart from each other by a second distance. The second distance is larger than the first distance.

### CROSS REFERENCE TO RELATED APPLICATIONS

The present application is based upon and claims the benefit of the priority from Japanese patent application No. 2020-053053, filed on Mar. 24, 2020, which is hereby incorporated by reference in its entirety.

### TECHNICAL FIELD

The present disclosure relates to quantum cascade lasers.

### BACKGROUND

Japanese Translation of PCT International Application Publication No. 2010-514163 discloses a quantum cascade laser having a plurality of mesa waveguides spaced apart from each other.

### SUMMARY

The present disclosure provides a quantum cascade laser including a first mesa waveguide provided on a substrate, the first mesa waveguide including a first core layer, a second mesa waveguide provided on the substrate, the second mesa waveguide including a second core layer, a first electrode electrically connected to the first mesa waveguide, and a second electrode electrically connected to the second mesa waveguide. The first mesa waveguide and the second mesa waveguide extend in a first direction. The first mesa waveguide and the second mesa waveguide are apart from each other by a first distance in a second direction, the second direction intersecting with the first direction. The first electrode and the second electrode are apart from each other by a second distance. The second distance is larger than the first distance.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a schematic plan view of a quantum cascade laser according to one embodiment.

FIG. 2 is a sectional view taken along line II-II in FIG. 1.

FIG. 3 is a sectional view taken along line III-III in FIG. 1.

FIG. 4 is a schematic sectional view of a quantum cascade laser according to another embodiment.

FIG. 5 is a schematic sectional view of a quantum cascade laser according to still another embodiment.

FIG. 6 is a schematic sectional view of a quantum cascade laser according to still another embodiment.

FIG. 7 is a schematic sectional view of a quantum cascade laser according to still another embodiment.

FIG. 8 is a schematic sectional view of a quantum cascade laser according to still another embodiment.

FIG. 9A shows a step of a method for producing a quantum cascade laser in FIG. 4.

FIG. 9B shows a step of the method for producing a quantum cascade laser in FIG. 4.

FIG. 9C shows a step of the method for producing a quantum cascade laser in FIG. 4.

FIG. 10A shows a step of the method for producing a quantum cascade laser in FIG. 4.

FIG. 10B shows a step of the method for producing a quantum cascade laser in FIG. 4.

FIG. 10C shows a step of the method for producing a quantum cascade laser in FIG. 4.

### DETAILED DESCRIPTION

### Problem to be Solved by the Present Disclosure

A quantum cascade laser array includes a plurality of mesa waveguides spaced apart from each other and electrodes each connected to the top face of the respective mesa waveguides. Since a distance between adjacent electrodes is usually the same as a distance between adjacent mesa waveguides, the distance between electrodes decreases as the distance between mesa waveguides decreases. This may cause discharge between adjacent electrodes.

The present disclosure provides a quantum cascade laser capable of reducing the possibility of discharge between adjacent electrodes.

### Description of Embodiments of the Present Disclosure

A quantum cascade laser in one embodiment includes a first mesa waveguide provided on a substrate, the first mesa waveguide including a first core layer, a second mesa waveguide provided on the substrate, the second mesa waveguide including a second core layer, a first electrode electrically connected to the first mesa waveguide, and a second electrode electrically connected to the second mesa waveguide. The first mesa waveguide and the second mesa waveguide extend in a first direction. The first mesa waveguide and the second mesa waveguide are apart from each other by a first distance in a second direction, the second direction intersecting with the first direction. The first electrode and the second electrode are apart from each other by a second distance. The second distance is larger than the first distance.

According to the above-mentioned quantum cascade laser, a distance between a first electrode and a second electrode can be increased, even if a distance between a first mesa waveguide and a second mesa waveguide is reduced. Thus the possibility of discharge between the first electrode and the second electrode can be reduced.

The first mesa waveguide may have a first side surface and a second side surface. The second mesa waveguide may have a third side surface and a fourth side surface. The first to fourth side surfaces may extend in the first direction. The second side surface may face to the third side surface, and the second distance may be larger than a distance between the first side surface and the fourth side surface. In this case, the distance between the first electrode and the second distance can be increased.

The above-mentioned quantum cascade laser may further include a first contact layer electrically connected to the first electrode and a top face of the first mesa waveguide, and a second contact layer electrically connected to the second electrode and a top face of the second mesa waveguide. The first contact layer may extend to a position opposite to the second side surface with respect to the first side surface in the second direction, and the second contact layer may extend to a position opposite to the third side surface with respect to the fourth side surface in the second direction. In this case, the distance between the first electrode and the second electrode can be increased by increasing the lengths of a first contact layer and a second contact layer in the second directions.

The above-mentioned quantum cascade laser may further include a first cladding layer disposed between the top face of the first mesa waveguide and the first contact layer, and a second cladding layer disposed between the top face of the second mesa waveguide and the second contact layer. The first cladding layer may extend to a position opposite to the second side surface with respect to the first side surface in the second direction. The second cladding layer may extend to a position opposite to the third side surface with respect to the fourth side surface in the second direction. In this case, current is injected from the first electrode into the first core layer through the first contact layer and the first cladding layer. If the first contact layer and the first cladding layer extend to a position outside the first side surface, electric resistance of the current path that runs from the first electrode to the first mesa waveguide decreases. Similarly, current is injected from the second electrode into the second core layer through the second contact layer and the second cladding layer. If the second contact layer and the second cladding layer extend to a position outside the fourth side surface, electric resistance of the current path that runs from the second electrode to the second mesa waveguide decreases.

The above-mentioned quantum cascade laser may further include an insulating layer disposed between the first electrode and the second electrode. The insulating layer may further decrease the possibility of discharge between the first electrode and the second electrode.

### DESCRIPTION OF THE EMBODIMENTS

Hereinafter, embodiments of the present disclosure will be described in detail with reference to the accompanying drawings. In the description of the drawings, the same reference numerals are used for the same or equivalent elements, and a repetitive description is omitted. In the drawings, an X-axis direction (first direction), a Y-axis direction (second direction), and a Z-axis direction which intersect with each other are shown as necessary. The X-axis direction, the Y-axis direction and the Z-axis direction are, for example, perpendicular to each other.

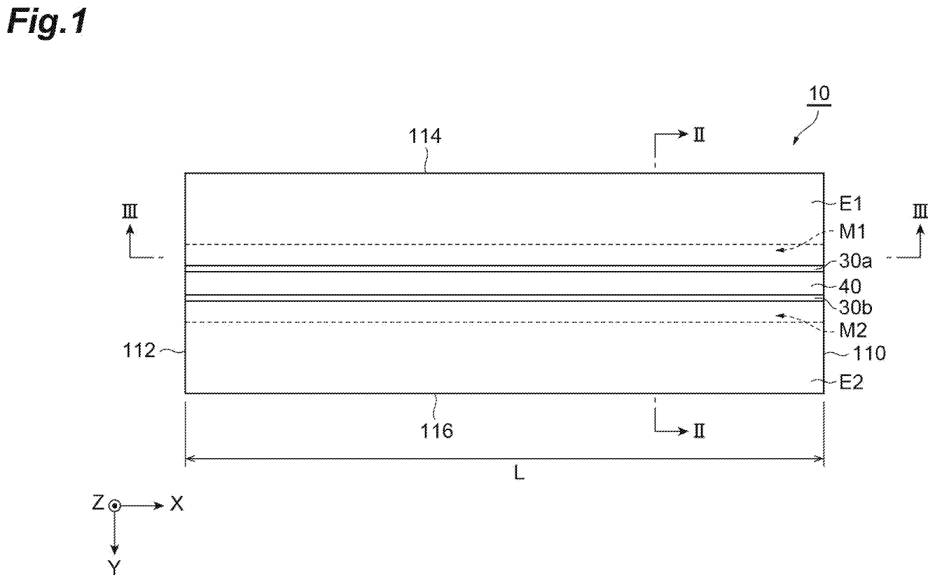

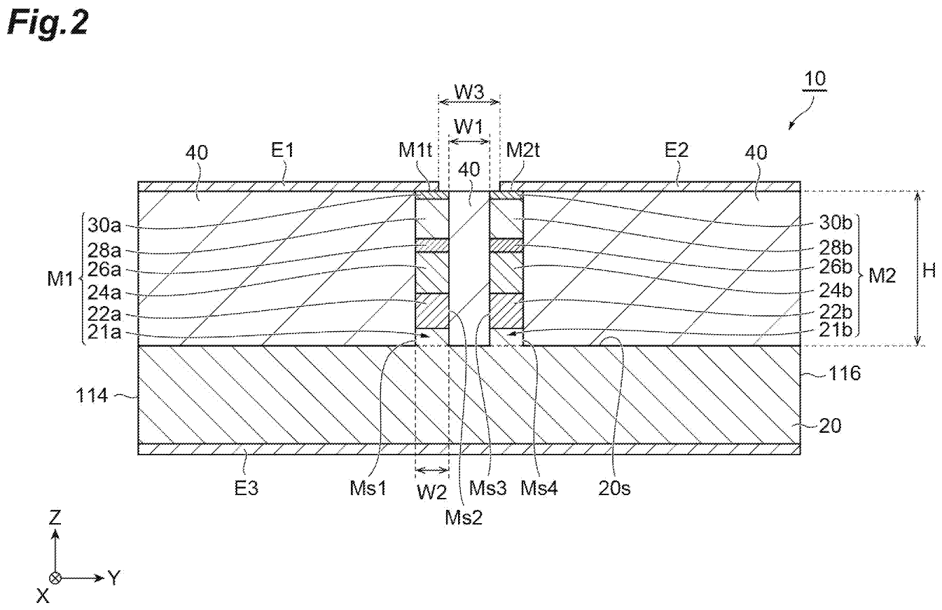

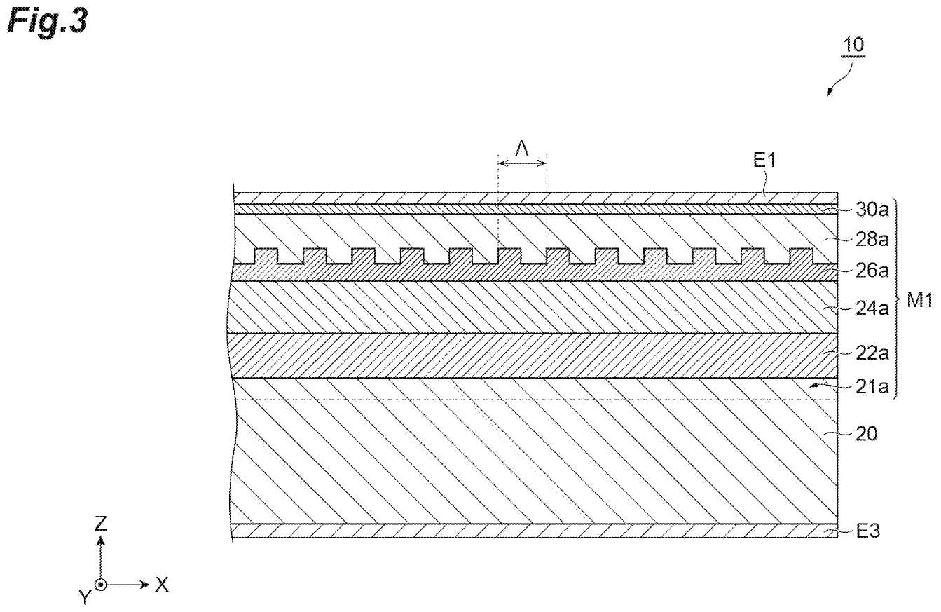

FIG. 1 is a plan view schematically showing a quantum cascade laser according to an embodiment. FIG. 2 is a sectional view taken along line II-II in FIG. 1. FIG. 3 is a sectional view taken along line III-III in FIG. 1.

A quantum cascade laser 10 shown in FIG. 1, FIG. 2, and FIG. 3 is used in, for example, an industrial laser processing apparatus or an optical measurement system for environmental analysis, industrial gas analysis, or medical diagnosis. Quantum cascade laser 10 is a resonator capable of oscillating a laser light in the X-axis direction.

The laser light may include, for example, infrared light such as mid-infrared light. Quantum cascade laser 10 has an output facet 110 for emitting a laser light in the X-axis direction and a reflection facet 112 opposed to output facet 110 in the X-axis direction. Output facet 110 is a front end surface. Reflection facet 112 is a rear end surface. Each of output facet 110 and reflection facet 112 may be perpendicular to the X-axis direction. Each of output facet 110 and reflection facet 112 has, for example, a rectangular shape. A low reflection film and a high reflection film may be formed on output facet 110 and reflection facet 112, respectively. Quantum cascade laser 10 has side surfaces 114 and 116 (fifth and sixth side surfaces, respectively) extending in the X-axis and the Z-axis directions. Each of side surfaces 114 and 116 has, for example, a rectangular shape. Quantum cascade laser 10 has, for example, a rectangular parallelepiped shape. Quantum cascade laser 10 has a length L of, for example, 1 mm to 3 mm in the X-axis direction.

Quantum cascade laser 10 includes a substrate 20, a first mesa waveguide M1 provided on substrate 20, and a second mesa waveguide M2 provided on substrate 20. First mesa waveguide M1 and second mesa waveguide M2 are monolithically integrated on substrate 20. First mesa waveguide M1 and second mesa waveguide M2 extend in the X-axis direction and are separated from each other in the Y-axis direction. First mesa waveguide M1 and second mesa waveguide M2 are provided on a principal surface 20s of substrate 20. More than two mesa waveguides may be provided on substrate 20.

First mesa waveguide M1 and second mesa waveguide M2 each have a width W2 (length in the Y-axis direction). Width W2 may be 3 μm or more, or 10 μm or less. A distance W1 between first mesa waveguide M1 and second mesa waveguide M2 may be greater than width W2. Distance W1 is the shortest distance between first mesa waveguide M1 and second mesa waveguide M2 in the Y-axis direction. Distance W1 may be measured in a plane including a top face M1t of first mesa waveguide M1 and a top face M2t of second mesa waveguide M2. Distance W1 may be 2 μm or more, 50 μm or more, 100 μm or less, 30 μm or less, or 10 μm or less.

First mesa waveguide M1 has a first side surface Ms1 and a second side surface Ms2. Second side surface Ms2 is opposed to first side surface Ms1. Second mesa waveguide M2 has a third side surface Ms3 and a fourth side surface Ms4. Fourth side surface Ms4 is opposed to third side surface Ms3. First side surface Ms1, second side surface Ms2, third side surface Ms3, and fourth side surface Ms4 extend in the X-axis direction and the Z-axis direction. Second side surface Ms2 faces third side surface Ms3. A distance between second side surface Ms2 and third side surface Ms3 corresponds to distance W1 described above. A distance between first side surface Ms1 and second side surface Ms2 and a distance between third side surface Ms3 and fourth side surface Ms4 correspond to width W2 described above.

First mesa waveguide M1 and second mesa waveguide M2 may be buried by a current blocking region 40. Current blocking region 40 covers first side surface Ms1, second side surface Ms2, third side surface Ms3, and fourth side surface Ms4. In this embodiment, quantum cascade laser 10 has a buried heterostructure.

Quantum cascade laser 10 includes a first electrode E1 electrically connected to first mesa waveguide M1 and a second electrode E2 electrically connected to second mesa waveguide M2. A third electrode E3 is provided on the back surface of substrate 20, the back surface being opposite to principal surface 20s.

First electrode E1 is connected to top face M1t of first mesa waveguide M1. First electrode E1 is provided on top face M1t of first mesa waveguide M1 and current blocking region 40. First electrode E1 extends in the Y-axis direction from the position between first side surface Ms1 and second side surface Ms2 to side surface 114 of quantum cascade laser 10.

Second electrode E2 is connected to top face M2t of second mesa waveguide M2. Second electrode E2 is provided on second mesa waveguide M2 and current blocking region 40. Second electrode E2 extends in the Y-axis direction from the position between third side surface Ms3 and fourth side surface Ms4 to side surface 116 of quantum cascade laser 10.

In this embodiment, the area between first electrode E1 and second electrode E2 is a gap. A distance W3 between first electrode E1 and second electrode E2 is greater than distance W1 between first mesa waveguide M1 and second mesa waveguide M2. Distance W3 is the shortest distance between first electrode E1 and second electrode E2 in the Y-axis direction. Distance W3 may be measured in a plane including top face M1t of first mesa waveguide M1 and top face M2t of second mesa waveguide M2. Distance W3 may be 30 μm or more, or 200 μm or less.

Substrate 20 is, for example, an n-type group III-V compound semiconductor substrate such as an n-type InP substrate.

First mesa waveguide M1 extends in the X-axis direction and protrudes from principal surface 20s of the substrate in the Z-axis direction. The X-axis direction is the longitudinal direction of first mesa waveguide M1. First mesa waveguide M1 has a height H measured from principal surface 20s of substrate 20. Height H may be 10 μm or more. First mesa waveguide M1 is a laminated body including a plurality of semiconductor layers laminated in the Z-axis direction. First mesa waveguide M1 includes a lower cladding layer 22a provided on a protruding portion 21a provided on principal surface 20s of substrate 20, a core layer 24a (first core layer) provided on lower cladding layer 22a, a grating layer 26a provided on core layer 24a, an upper cladding layer 28a provided on grating layer 26a, and a contact layer 30a provided on upper cladding layer 28a. In the Z-axis direction, protruding portion 21a, lower cladding layer 22a, core layer 24a, grating layer 26a, upper cladding layer 28a and contact layer 30a are arranged in order. First electrode E1 is arranged on contact layer 30a. Core layer 24a also functions as a light-emitting layer. The light oscillated from a quantum cascade laser capable of oscillating mid-infrared light has the oscillation wavelength of, for example, 3 μm to 20 μm, which is longer than that of a laser for communication. Thus the light is spread over a range wider than a cross section of a core layer when propagating through the waveguide of quantum cascade laser. In order to cover a light distribution range, height H in one or more embodiments may be 10 μm or more, and the thicknesses of upper cladding layer 28a and lower cladding layer 22a in one or more embodiments may be 3 μm or more, for example.

Second mesa waveguide M2 extends in the X-axis direction and protrudes from principal surface 20s of a substrate in the Z-axis direction. The X-axis direction is the longitudinal direction of the second mesa waveguide M2. Second mesa waveguide M2 has height H measured from principal surface 20s of substrate 20. Second mesa waveguide M2 is a laminated body including a plurality of semiconductor layers laminated in the Z-axis direction. Second mesa waveguide M2 includes a lower cladding layer 22b provided on a protruding portion 21b provided on principal surface 20s of substrate 20, a core layer 24b (second core layer) provided on lower cladding layer 22b, a grating layer 26b provided on core layer 24b, an upper cladding layer 28b provided on grating layer 26b, and a contact layer 30b provided on upper cladding layer 28b. In the Z-axis direction, protruding portion 21b, lower cladding layer 22b, core layer 24b, grating layer 26b, upper cladding layer 28b and contact layer 30b are arranged in order. A second electrode E2 is arranged on contact layer 30b. Core layer 24b also functions as a light-emitting layer.

Protruding portions 21a and 21b include the same material as substrate 20.

Lower cladding layers 22a and 22b and upper cladding layers 28a and 28b are n-type group III-V compound semiconductor layers such as n-type InP layers. InP is transparent to mid-infrared light. The thickness of each of lower cladding layers 22a and 22b and upper cladding layers 28a and 28b may be 2 μm or more. Lower cladding layers 22a and 22b may be omitted, and protruding portions 21a and 21b and substrate 20 may function as lower cladding layers.

Core layers 24a and 24b have a structure in which a plurality of active layers and a plurality of injection layers are alternately laminated. Each of the active layers and the injection layers has a superlattice structure in which a plurality of well layers and a plurality of barrier layers are alternately laminated. Each of the well layers and the barrier layers has a thickness of several nm. A GaInAs/AlInAs superlattice or a GaInAsP/AlInAs superlattice may be used, for example. Only electrons can act as carriers. A laser light in the mid-infrared region with a wavelength of, for example, 3 μm to 20 μm is oscillated by subband transition in the conduction band.

Grating layer 26a has a plurality of recesses periodically arranged with a pitch Λ along the X-axis direction. Each recess is a groove extending in the Y-axis direction. Grating layer 26b has the same configuration as that of grating layer 26a except for pitch Λ. Pitch Λ defines the oscillation wavelength λ of the laser light. The wavelength of the laser light emitted from first mesa waveguide M1 and that of the laser light from second mesa waveguide M2 are thus different from each other. Grating layers 26a and 26b allow quantum cascade laser 10 to function as a distributed feedback (DFB) laser.

Quantum cascade laser 10 allows single-mode oscillations. The recesses of grating layers 26a and 26b are filled with upper cladding layers 28a and 28b. Grating layers 26a and 26b are group III-V compound semiconductor layers such as unintentionally doped or n-type GaInAs layers.

Contact layers 30a and 30b are n-type group III-V compound semiconductor layers such as n-type GaInAs layers. Contact layer 30a is in ohmic contact with first electrode E1. Contact layer 30b is in ohmic contact with second electrode E2. The thicknesses of contact layers 30a and 30b may be 500 nm or less. Contact layers 30a and 30b may be omitted, and upper cladding layers 28a and 28b may function as contact layers.

One or more optical confinement layers may be provided between lower cladding layers 22a and 22b and core layers 24a and 24b. One or more optical confinement layers may be provided between grating layers 26a and 26b and core layers 24a and 24b. The optical confinement layers are group III-V compound semiconductor layers such as unintentionally doped or n-type GaInAs layers.

For example, Si, S, Sn, Se can be used as an n-type dopant.

Current blocking region 40 may be unintentionally doped or semi-insulating group III-V compound semiconductor region. Current blocking region 40 has a high resistance of, for example, 10⁵ Ωcm or more to electrons. The semi-insulating group III-V compound semiconductor region is a region (an InP region, a GaInAs region, an AlInAs region, a GaInAsP region or an AlGaInAs region) doped with a transition metal such as Fe, Ti, Cr or Co.

Each of first electrode E1, second electrode E2, and third electrode E3 is, for example, a Ti/Au film, a Ti/Pt/Au film, or a Ge/Au film.

Quantum cascade laser 10 may be operated as follows. As voltage is applied between first electrode E1 and third electrode E3 to cause current to flow into core layer 24a, a laser light having a first wavelength is oscillated from first mesa waveguide M1. Similarly, as voltage is applied between second electrode E2 and third electrode E3 to cause current to flow into core layer 24b, a laser light having a second wavelength is oscillated from second mesa waveguide M2. The laser light having a second wavelength may be oscillated at timings different from those of the laser light having a first wavelength. The voltage applied to the electrodes may be 10 V or more, which is higher than the voltage applied to, for example, a semiconductor laser used for communication with its wavelength band of 1.3 μm or 1.55 μm. Higher drive voltages tend to cause discharges between electrodes during arraying. In quantum cascade laser 10 according to the present embodiment, distance W3 between electrodes can be increased. Thus the possibility of discharge can be reduced.

According to quantum cascade laser 10 of the present embodiment, distance W3 between first electrode E1 and second electrode E2 can be increased even if distance W1 between first mesa waveguide M1 and second mesa waveguide M2 is reduced. The possibility of discharge between first electrode E1 and second electrode E2 can thus be reduced even if there is any defective portion which serves as a starting point of discharge, such as a protrusion, a chipping, a crack, or an attachment of foreign matter in, for example, first electrode E1 or second electrode E2. Quantum cascade laser 10 can thus be operated as follows. For example, when a voltage is applied between first electrode E1 and third electrode E3 but not to second electrode E2, the laser light is emitted from first mesa waveguide M1, but not from second mesa waveguide M2. Similarly, when a voltage is applied between second electrode E2 and third electrode E3 but not to first electrode E1, the laser light is emitted from second mesa waveguide M2, but not from first mesa waveguide M1.

If distance W1 can be reduced, quantum cascade laser 10 can be reduced in size. In addition, a large number of mesa waveguides (e.g., three or more mesa waveguides) capable of emitting laser light of mutually differing wavelengths can be arranged on substrate 20. Furthermore, when distance W1 is small, a lens can be shared to collect or collimate the laser lights emitted from a large number of mesa waveguides.

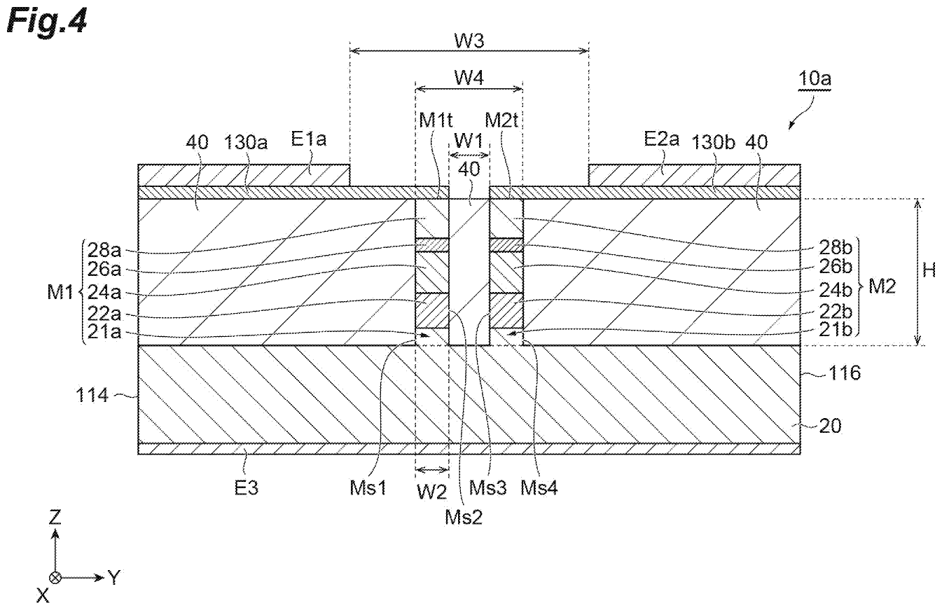

FIG. 4 is a sectional view schematically showing a quantum cascade laser according to another embodiment. A quantum cascade laser 10a shown in FIG. 4 has the same configuration as that of quantum cascade laser 10 of FIG. 2 except that quantum cascade laser 10a includes contact layers 130a and 130b instead of contact layers 30a and 30b, and first electrode E1a and second electrode E2a instead of first electrode E1 and second electrode E2. In this embodiment, first mesa waveguide M1 and second mesa waveguide M2 do not include contact layers 30a and 30b. Contact layers 130a and 130b have the same configuration as that of contact layers 30a and 30b except for the shape. First electrode E1a and second electrode E2a have the same configuration as that of first electrode E1 and second electrode E2 except for the shape.

Contact layer 130a (first contact layer) is provided on top face M1t of first mesa waveguide M1 and current blocking region 40. First electrode E1a is provided on contact layer 130a. Thus, contact layer 130a is electrically connected to top face M1t of first mesa waveguide M1 and first electrode E1a. Contact layer 130a extends outwardly in the Y-axis direction to a position opposed to second side surface Ms2 with respect to first side surface Ms1. Contact layer 130a extends from second side surface Ms2 to side surface 114 of quantum cascade laser 10a in the Y-axis direction.

Contact layer 130b (second contact layer) is provided on top face M2t of second mesa waveguide M2 and current blocking region 40. Second electrode E2a is provided on contact layer 130b. Thus, contact layer 130b is electrically connected to top face M2t of second mesa waveguide M2 and second electrode E2a. Contact layer 130b extends outwardly in the Y-axis direction to a position opposed to third side surface Ms3 with respect to fourth side surface Ms4. Contact layer 130b extends from third side surface Ms3 to side surface 116 of quantum cascade laser 10a in the Y-axis direction.

First electrode E1a extends from a position outside first side surface Ms1 to side surface 114 of quantum cascade laser 10a in the Y-axis direction.

Second electrode E2a extends from a position outside fourth side surface Ms4 to side surface 116 of quantum cascade laser 10a in the Y-axis direction.

In the present embodiment, distance W3 between first electrode E1a and second electrode E2a is larger than a distance W4 between first side surface Ms1 and fourth side surface Ms4. Distance W4 is the shortest distance between first side surface Ms1 and fourth side surface Ms4 in the Y-axis direction. Distance W4 may be measured in a plane including top face M1t of first mesa waveguide M1 and top face M2t of second mesa waveguide M2.

Quantum cascade laser 10a in this embodiment can yield the same effects as those of quantum cascade laser 10. In addition, distance W3 between first electrode E1a and second electrode E2a can be increased. For example, by increasing the length of contact layers 130a and 130b in the Y-axis direction, distance W3 between first electrode E1a and second electrode E2a can be increased.

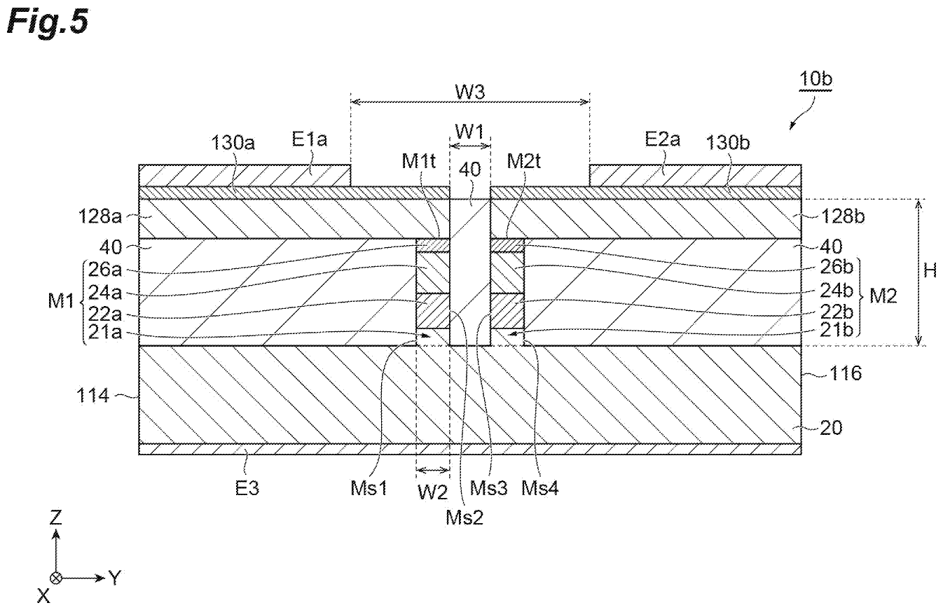

FIG. 5 is a sectional view schematically showing a quantum cascade laser according to still another embodiment. A quantum cascade laser 10b shown in FIG. 5 has the same configuration as that of quantum cascade laser 10a of FIG. 4 except that upper cladding layers 128a and 128b are provided instead of upper cladding layers 28a and 28b. In the present embodiment, first mesa waveguide M1 and second mesa waveguide M2 do not include upper cladding layers 28a and 28b. Upper cladding layers 128a and 128b have the same configuration as that of upper cladding layers 28a and 28b except for the shape.

Upper cladding layer 128a (first cladding layer) is provided on top face M1t of first mesa waveguide M1 and current blocking region 40. A contact layer 130a is provided on upper cladding layer 128a. This means that upper cladding layer 128a is disposed between top face M1t of first mesa waveguide M1 and contact layer 130a. Upper cladding layer 128a extends outwardly in the Y-axis direction to a position opposed to second side surface Ms2 with respect to first side surface Ms1. Upper cladding layer 128a extends from second side surface Ms2 to side surface 114 of quantum cascade laser 10b in the Y-axis direction. The length of upper cladding layer 128a may be different from that of contact layer 130a in the Y-axis direction.

Upper cladding layer 128b (second cladding layer) is provided on top face M2t of second mesa waveguide M2 and current blocking region 40. Contact layer 130b is provided on upper cladding layer 128b. This means that upper cladding layer 128b is disposed between top face M2t of second mesa waveguide M2 and contact layer 130b. Upper cladding layer 128b extends outwardly in the Y-axis direction to a position opposed to third side surface Ms3 with respect to fourth side surface Ms4. Upper cladding layer 128b extends from third side surface Ms3 to side surface 116 of quantum cascade laser 10b in the Y-axis direction. The length of upper cladding layer 128b may be different from that of contact layer 130b in the Y-axis direction.

Quantum cascade laser 10b in the present embodiment can yield the same effects as those of quantum cascade laser 10a. In quantum cascade laser 10b, current is injected from first electrode E1a into core layer 24a through contact layer 130a and upper cladding layer 128a. If contact layer 130a and upper cladding layer 128a extend to a position outside the first side surface Ms1, electric resistance of the current path that runs from first electrode E1a into first mesa waveguide M1 through contact layer 130a and upper cladding layer 128b is reduced. Similarly, current is injected from second electrode E2a into core layer 24b through contact layer 130b and upper cladding layer 128b. When contact layer 130b and upper cladding layer 128b extend to a position outside fourth side surface Ms4, electric resistance of the current path that runs from second electrode E2a into second mesa waveguide M2 through contact layer 130b and upper cladding layer 128b is reduced. A power consumption of quantum cascade laser 10b can thus be reduced.

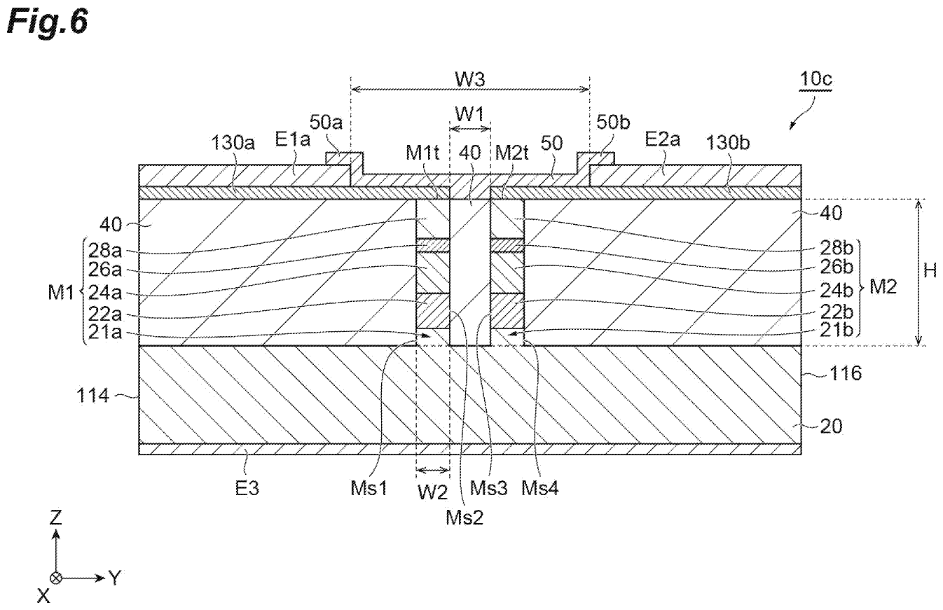

FIG. 6 is a sectional view schematically showing a quantum cascade laser according to still another embodiment. A quantum cascade laser 10c shown in FIG. 6 has the same configuration as that of quantum cascade laser 10a shown FIG. 4 except that quantum cascade laser 10c further includes an insulating layer 50. Insulating layer 50 is disposed between first electrode E1a and second electrode E2a. Although one end portion 50a of insulating layer 50 in the Y-axis direction reaches the upper surface of first electrode E1a in FIG. 6, it may terminate at the end surface of first electrode E1a. Although the other end portion 50b of insulating layer 50 in the Y-axis direction reaches the upper surface of second electrode E2a in FIG. 6, it may terminate at the end surface of second electrode E2a. Examples of materials for insulating layer 50 include SiO₂, SiON, SiN, alumina, benzocyclobutene, and polyimide.

Quantum cascade laser 10c according to the present embodiment can yield the same effects as those of quantum cascade laser 10a. In addition, insulating layer 50 improves the dielectric strength between first electrode E1a and second electrode E2a. The possibility of discharge between first electrode E1a and second electrode E2a can thus be reduced further. Insulating layer 50 can reduce the oxidation of contact layers 130a and 130b, and current blocking region 40 between contact layers 130a and 130b. Insulating layer 50 improves the mechanical strength of quantum cascade laser 10c.

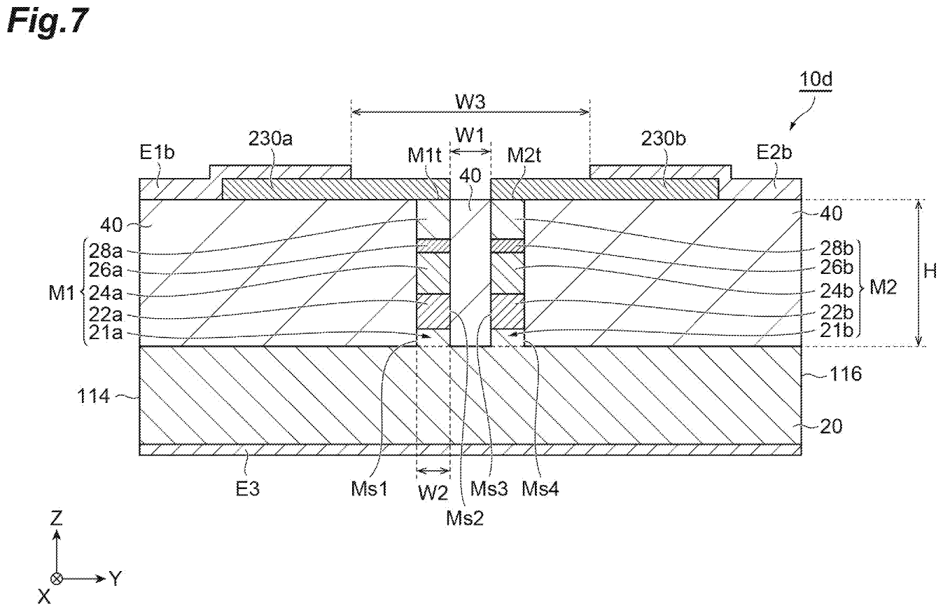

FIG. 7 is a sectional view showing quantum cascade laser according to still another embodiment. A quantum cascade laser 10d shown in FIG. 7 has the same configuration as that of quantum cascade laser 10a in FIG. 4 except that quantum cascade laser 10d includes contact layers 230a and 230b instead of contact layers 130a and 130b, and includes first electrode E1b and second electrode E2b instead of first electrode E1a and second electrode E2a. Contact layers 230a and 230b have the same configuration as that of contact layers 130a and 130b except for the shape. First electrode E1b and second electrode E2b have the same configuration as that of first electrode E1a and second electrode E2a except for the shape.

Contact layer 230a has the same configuration as that of contact layer 130a except that contact layer 230a extends in the Y-axis direction from second side surface Ms2 to a position between side surface 114 of quantum cascade laser 10d and first side surface Ms1. First electrode E1b has the same configuration as that of first electrode E1a except that first electrode E1b contacts current blocking region 40 in the area ranging from the position between side surface 114 of quantum cascade laser 10d and first side surface Ms1 to side surface 114.

Contact layer 230b has the same configuration as that of contact layer 130b except that contact layer 230b extends in the Y-axis direction from third side surface Ms3 to a position between side surface 116 of quantum cascade laser 10d and fourth side surface Ms4. Second electrode E2b has the same configuration as that of second electrode E2a except that second electrode E2b contacts current blocking region 40 in the area ranging from the position between side surface 116 of quantum cascade laser 10d and fourth side surface Ms4 to side surface 116.

Quantum cascade laser 10d of the present embodiment can yield the same effects as those of quantum cascade laser 10a. In addition, when performed with cleavage, side surfaces 114 and 116 of quantum cascade laser 10d can be formed without cutting contact layers 230a and 230b. Therefore, damage to contact layers 230a and 230b due to cleavage can be reduced.

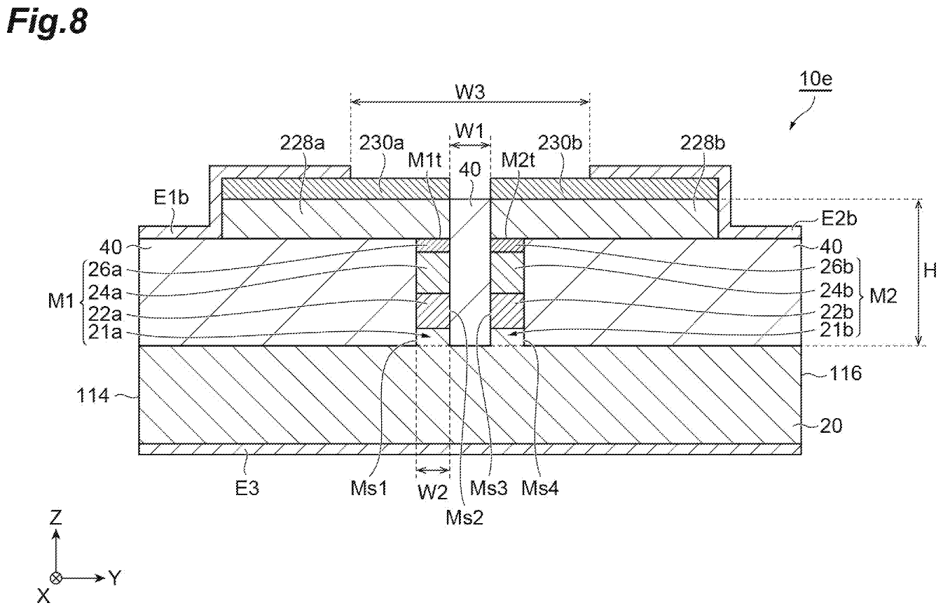

FIG. 8 is a sectional view schematically showing a quantum cascade laser according to still another embodiment. A quantum cascade laser 10e shown in FIG. 8 has the same configuration as that of quantum cascade laser 10d shown in FIG. 7 except that upper cladding layers 228a and 228b are provided instead of upper cladding layers 28a and 28b. In the present embodiment, first mesa waveguide M1 and second mesa waveguide M2 do not include upper cladding layers 28a and 28b. Upper cladding layers 228a and 228b have the same configuration as that of upper cladding layers 28a and 28b except for the shape.

Upper cladding layer 228a (first cladding layer) is provided on top face M1t of first mesa waveguide M1 and current blocking region 40. A contact layer 230a is provided on upper cladding layer 228a. This means that upper cladding layer 228a is disposed between top face M1t of first mesa waveguide M1 and contact layer 230a. Upper cladding layer 228a extends outward in the Y-axis direction to a position opposed to second side surface Ms2 with respect to first side surface Ms1. Upper cladding layer 228a extends in the Y-axis direction from second side surface Ms2 to a position between side surface 114 of quantum cascade laser 10e and first side surface Ms1.

Upper cladding layer 228b (second cladding layer) is provided on top face M2t of second mesa waveguide M2 and current blocking region 40. A contact layer 230b is provided on upper cladding layer 228b. This means that upper cladding layer 228b is disposed between top face M2t of second mesa waveguide M2 and contact layer 230b. Upper cladding layer 228b extends outwardly in the Y-axis direction to a position opposed to third side surface Ms3 with respect to fourth side surface Ms4. Upper cladding layer 228b extends in the Y-axis direction from third side surface Ms3 to a position between side surface 116 of quantum cascade laser 10e and fourth side surface Ms4.

Quantum cascade laser 10e of the present embodiment can yield the same effects as those of quantum cascade 10d. In quantum cascade laser 10e, current is injected from first electrode E1b to core layer 24a through contact layer 230a and upper cladding layer 228a. When contact layer 230a and upper cladding layer 228a extend to a position outside first side surface Ms1, the electric resistance of the current path that runs from first electrode E1b to first mesa waveguide M1 through contact layer 230a and upper cladding layer 228a is reduced. Similarly, current is injected from second electrode E2b to core layer 24b through contact layer 230b and upper cladding layer 228b. When contact layer 230b and upper cladding layer 228b extend to a position outside fourth side surface Ms4, the electric resistance of the current path that runs from second electrode E2b to second mesa waveguide M2 through contact layer 230b and upper cladding layer 228b is reduced. A power consumption of quantum cascade laser 10e can thus be reduced. Furthermore, when performed with cleavage, side surfaces 114 and 116 of quantum cascade laser 10e can be formed without cutting contact layers 230a and 230b and upper cladding layers 228a and 228b. Therefore, damage to contact layers 230a and 230b and upper cladding layers 228a and 228b due to cleavage can be reduced.

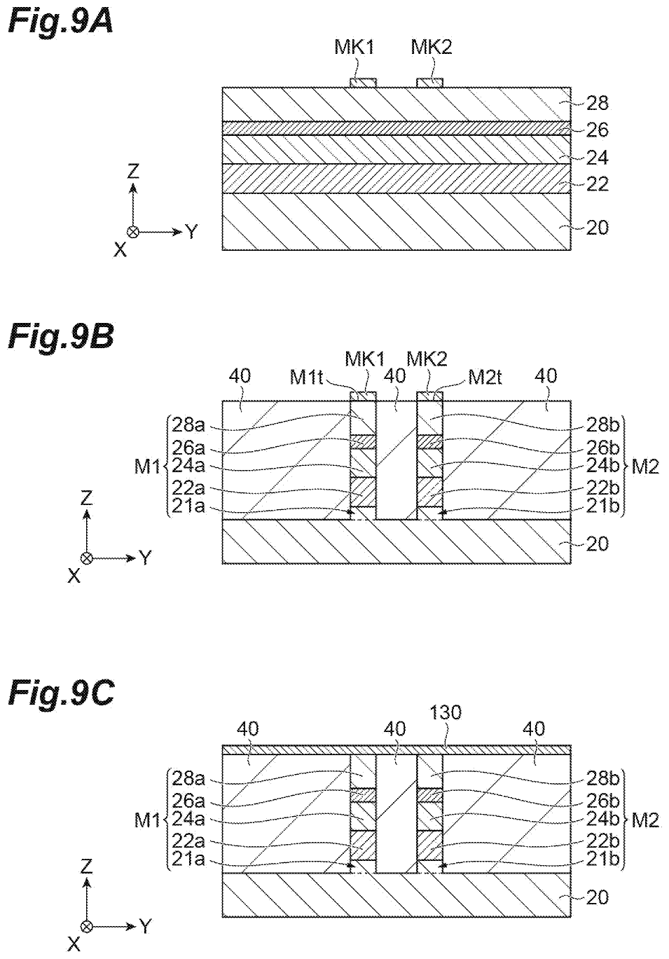

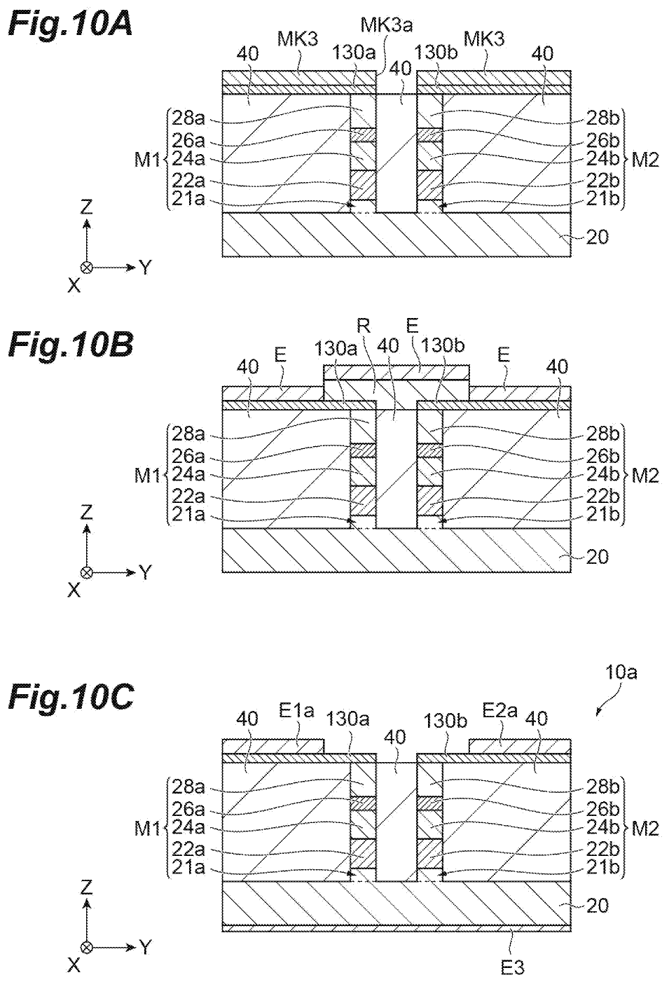

Hereinafter, examples of manufacturing method of quantum cascade laser 10a in FIG. 4 will be described referring to FIG. 9A, FIG. 9B, FIG. 9C, FIG. 10A, FIG. 10B and FIG. 10C. FIG. 9A to FIG. 10C each show the respective step of manufacturing method of quantum cascade laser 10a shown in FIG. 4.

As shown in FIG. 9A, a semiconductor layer 22 for lower cladding layers 22a and 22b, a semiconductor layer 24 for core layers 24a and 24b, a semiconductor layer 26 for grating layers 26a and 26b, and a semiconductor layer 28 for upper cladding layers 28a and 28b are sequentially formed on substrate 20. Each semiconductor layer can be grown, for example, by molecular beam epitaxy or organometallic vapor phase epitaxy methods. Semiconductor layer 26 has a plurality of grooves periodically arranged with pitch Λ (refer to FIG. 3). The grooves can be formed by, for example, photolithography and etching. After forming grooves in semiconductor layer 26, semiconductor layer 28 is grown to fill the grooves of semiconductor layer 26.

Subsequently, a mask MK1 for first mesa waveguide M1 and a mask MK2 for second mesa waveguide M2 are formed on semiconductor layer 28. Masks MK1 and MK2 may be formed by, for example, photolithography and etching. Masks MK1 and MK2 include, for example, insulating materials. Examples of insulating materials include SiN, SiON, SiO₂, alumina, and the like.

Next, as shown in FIG. 9B, first mesa waveguide M1 and second mesa waveguide M2 are formed by etching semiconductor layers 28, 26, 24, and 22, and a part of substrate 20 using masks MK1 and MK2. Examples of etching include dry etching or wet etching. Examples of dry etching include reactive ion etching with an etching gas. The dry etching depth is, for example, 10 μm or more.

Subsequently, current blocking region 40 is grown to bury first mesa waveguide M1 and second mesa waveguide M2 using masks MK1 and MK2. Current blocking region 40 containing a compound semiconductor can be favorably formed using an organometallic vapor phase epitaxy (OMVPE) method by setting distance W1 between the waveguides to be 2 μm or more. This can be done when the heights of first mesa waveguide M1 and second mesa waveguide M2 are 10 μm or more.

As shown in FIG. 9C, after removing masks MK1 and MK2, a semiconductor layer 130 for contact layers 130a and 130b is formed on first mesa waveguide M1, second mesa waveguide M2, and current blocking region 40.

Next, as shown in FIG. 10A, a mask MK3 is formed on semiconductor layer 130. Mask MK3 has an opening MK3a in an area between first mesa waveguide M1 and second mesa waveguide M2. Subsequently, semiconductor layer 130 is etched using mask MK3 to form contact layers 130a and 130b.

As shown in FIG. 10B, after removing mask MK3, a resist pattern R is formed on first mesa waveguide M1 and second mesa waveguide M2.

Subsequently, a metal film E for first electrode E1a and second electrode E2a is formed on resist pattern R. Metal film E may be formed, for example, by vapor deposition, sputtering, or the like.

Next, as shown in FIG. 10C, first electrode E1a and second electrode E2a are formed by removing resist pattern R and metal film E on resist pattern R by the lift-off method.

Subsequently, substrate 20 is thinned down to a thickness of, for example, 100 μm to 200 μm by polishing or the like. Then, third electrode E3 is formed on the back surface of substrate 20. Quantum cascade laser 10a shown in FIG. 4 can be obtained by cleaving substrate 20.

Quantum cascade lasers 10, 10b, 10c, 10d, and 10e can be manufactured in the same manner. For example, quantum cascade laser 10 shown in FIGS. 1 to 3 can be manufactured by forming semiconductor layer 130 on semiconductor layer 28 prior to forming masks MK1 and MK2. Mask MK3 is formed in such a manner that a part of top face M1t of first mesa waveguide M1 and a part of top face M2t of second mesa waveguide M2 are exposed in opening MK3a of mask MK3.

Quantum cascade laser 10b shown in FIG. 5 can be manufactured by forming semiconductor layers 28 and 130 after removing masks MK1 and MK2 without forming semiconductor layer 28 prior to forming masks MK1 and MK2.

Quantum cascade laser 10c shown in FIG. 6 can be manufactured by forming insulating layer 50 by, for example, photolithography and etching, after forming first electrode E1a and second electrode E2a.

Quantum cascade laser 10d shown in FIG. 7 can be manufactured by forming an opening in mask MK3 in a region outwardly away from first side surface Ms1 of first mesa waveguide M1 in the Y-axis direction and in a region outwardly away from fourth side surface Ms4 of second mesa waveguide M2 in the Y-axis direction.

Quantum cascade laser 10e shown in FIG. 8 can be manufactured by growing current blocking region 40 to bury first mesa waveguide M1 and second mesa waveguide M2 using masks MK1 and MK2 without forming semiconductor layer 28 prior to forming masks MK1 and MK2. After removing masks MK1 and MK2, semiconductor layers 28 and 130 are grown. Then, semiconductor layers 28 and 130 between the two mesa waveguides are etched away to form a gap only between first mesa waveguide M1 and second mesa waveguide M2 by using mask MK3 having opening MK3a extending in the X-axis direction. Current blocking region 40 is further grown in the gap. Then, mask MK3 is removed. Using a mask having an opening extending in the X-axis direction, semiconductor layers 28 and 130 located in the opening are etched only in a region away from first side surface Ms1 of first mesa waveguide M1 in the Y-axis direction and in a region away from fourth side surface Ms4 of second mesa waveguide M2 in the Y-axis direction. As a result, upper cladding layers 228a and 228b and contact layers 230a and 230b are formed.

Whereas the principles of the present disclosure have been illustrated and described with reference to preferred embodiments, the present disclosure is not limited to any particular configuration disclosed in the embodiments.

The components of each embodiment may be combined with each other. For example, quantum cascade lasers 10, 10b, 10d, and 10e may each include insulating layer 50.

Quantum cascade laser 10 shown in FIG. 1 to FIG. 3 may include first electrode E1 connected to a side surface of contact layer 30a (the surface included in first side surface Ms1) instead of an upper surface of contact layer 30a, and second electrode E2 connected to a side surface of contact layer 30b (the surface included in fourth side surface Ms4) instead of an upper surface of contact layer 30b.

Quantum cascade laser 10d shown in FIG. 7 may include first electrode E1b connected to a side surface of contact layer 230a and second electrode E2b connected to a side surface of contact layer 230b. In this embodiment, any part of first electrode E1b is not located on the upper surface of contact layer 230a. Similarly, any part of electrode E2b is not located on the upper surface of contact layer 230b. Therefore, distance W3 between the first electrode E1b and second electrode E2b can be increased.

Quantum cascade lasers 10, 10a, 10b, 10c, 10d, and 10e may not include grating layers 26a and 26b. Each quantum cascade laser then operates as a Fabry-Perot laser rather than a distributed feedback laser.

Quantum cascade laser 10 may not include current blocking region 40. In this case, an insulating layer is formed on first side surface Ms1, second side surface Ms2, third side surface Ms3, and fourth side surface Ms4.

What is claimed is:

1. A quantum cascade laser comprising:
a first mesa waveguide provided on a substrate, the first mesa waveguide including a first core layer;
a second mesa waveguide provided on the substrate, the second mesa waveguide including a second core layer;
a first electrode electrically connected to the first mesa waveguide; and
a second electrode electrically connected to the second mesa waveguide,
wherein
the first mesa waveguide and the second mesa waveguide extend in a first direction,
the first mesa waveguide and the second mesa waveguide are apart from each other by a first distance in a second direction, the second direction intersecting with the first direction,
the first electrode and the second electrode are apart from each other by a second distance, and
the second distance is larger than the first distance.

2. The quantum cascade laser according to claim 1, wherein
the first mesa waveguide comprises a first side surface and a second side surface,
the second mesa waveguide comprises a third side surface and a fourth side surface,
the first to fourth side surfaces extend in the first direction,
the second side surface faces to the third side surface, and
the second distance is larger than a distance between the first side surface and the fourth side surface.

3. The quantum cascade laser according to claim 2 further comprising:
a first contact layer electrically connected to the first electrode and a top face of the first mesa waveguide; and
a second contact layer electrically connected to the second electrode and a top face of the second mesa waveguide,
wherein
the first contact layer extends to a position opposite to the second side surface with respect to the first side surface in the second direction, and
the second contact layer extends to a position opposite to the third side surface with respect to the fourth side surface in the second direction.

4. The quantum cascade laser according to claim 3 further comprising:
a first cladding layer disposed between the top face of the first mesa waveguide and the first contact layer; and
a second cladding layer disposed between the top face of the second mesa waveguide and the second contact layer,
wherein
the first cladding layer extends to a position opposite to the second side surface with respect to the first side surface in the second direction, and
the second cladding layer extends to a position opposite to the third side surface with respect to the fourth side surface in the second direction.

5. The quantum cascade laser according to claim 1 further comprising an insulating layer disposed between the first electrode and the second electrode.

6. The quantum cascade laser according to claim 1, wherein the first distance is 30 μm or less.

7. The quantum cascade laser according to claim 1, wherein the second distance is 30 μm or more.

8. The quantum cascade laser according to claim 3, wherein
the quantum cascade laser comprises fifth and sixth side surfaces extending in the first direction,
the first contact layer extends from the second side surface to a position between the fifth side surface and the first side surface in the second direction, and
the second contact layer extends from the third side surface to a position between the sixth side surface and the fourth side surface in the second direction.

9. The quantum cascade laser according to claim 4, wherein
the quantum cascade laser comprises fifth and sixth side surfaces extending in the first direction,
the first cladding layer extends from the second side surface to a position between the fifth side surface and the first side surface in the second direction, and
the second cladding layer extends from the third side surface to a position between the sixth side surface and the fourth side surface in the second direction.
